(19) United States
(12) Patent Application Publication
(10) Pub. No.: US 2010/0276675 A1
(43) Pub. Date: Nov. 4, 2010

(54) LIGHT-EMITTING DEVICE

(76) Inventors: Reiko Taniguchi, Osaka (JP); Masayuki Ono, Osaka (JP); Shogo Nasu, Hyogo (JP); Eiichi Satoh, Osaka (JP); Takayuki Shimamura, Osaka (JP); Masaru Odagiri, Hyogo (JP)

Correspondence Address: MCDERMOTT WILL & EMERY LLP, 600 13TH STREET, NW, WASHINGTON, DC, 20005-3096, US

(21) Appl. No.: 12/746,434

(22) PCT Filed: Dec. 3, 2008
(86) PCT No.: PCT/JP2008/003574

§ 371 Date: Jun. 4, 2010

(30) Foreign Application Priority Data
Dec. 5, 2007 (JP) 2007-314273
Feb. 5, 2008 (JP) 2008-024849

(51) Int. Cl. H01L 51/54; H01L 33/44

(52) U.S. Cl. 257/40; 257/98; 257/E33.061; 257/E51.027

(57) ABSTRACT

Disclosed is a light emitting device including a pair of electrodes at least one of which is transparent or semi-transparent, and a phosphor layer arranged between the pair of electrodes. The phosphor layer contains phosphor particles dispersed therein, and conductive nano particles are interposed at the interface between the phosphor layer and one of the electrodes. Also disclosed is another light emitting device including a pair of electrodes at least one of which is transparent or semi-transparent, and a phosphor layer arranged between the pair of electrodes. In this light emitting device, the phosphor layer contains phosphor particles dispersed therein, and at least one of the pair of electrodes is provided with a brush-like electrode projecting towards the phosphor layer. The brush-like electrode may be provided on the electrode on the positive electrode side, and the brush-like electrode provided on the electrode on the positive electrode side may preferably have a work function of 4.5 eV or more.

### BACKGROUND

1. Technical Field

The present application claims the priorities of Japanese Patent Application No. 2007-314273 filed on Dec. 5, 2007 in Japan and Japanese Patent Application No. 2008-24849 filed on Feb. 5, 2008 in Japan, the contents of which are hereby incorporated by reference.

The present invention relates to a light-emitting device for electro-luminescence.

2. Description of the Related Art

In recent years, electroluminescence elements (hereinafter, referred to as EL elements) have attracted attention as light and thin surface-emitting elements. The EL elements are broadly divided into organic EL elements in which a direct-current voltage is applied to a fluorescent substance made of an organic material to recombine electrons and holes for light emission, and inorganic EL elements in which an alternating voltage is applied to a fluorescent substance made of an inorganic material to induce electrons accelerated in a high electric field of approximately 10⁶ V/cm to collide with the luminescent center of the inorganic fluorescent substance for excitation of the electrons, and permit the inorganic fluorescent substance to emit light in the relaxation process.

The inorganic EL elements include dispersion EL elements in which inorganic fluorescent substance particles are dispersed in a binder made of a polymer organic material to serve as a light emitting layer, and thin-film EL elements in which an insulating layer is provided on one or both sides of a thin-film light emitting layer with a thickness on the order of 1 μm. Among these elements, the dispersion EL elements have attracted attention because of the advantages of their lower power consumption and even lower manufacturing cost due to their simpler manufacturing processes.

The EL element 100 referred to as a dispersion EL element will be described using FIG. 9. Conventional EL elements have a layered structure including a substrate 101, a first electrode 102, a light emitting layer 103, an insulator layer 104, and a second electrode 105 in order from the substrate side. The light emitting layer 103 includes inorganic fluorescent substance particles such as ZnS:Mn dispersed in an organic binder, and the insulator layer 104 includes a strong insulator such as BaTiO₃ dispersed in an organic binder. An alternating-current power supply 106 is placed between the first electrode 102 and the second electrode 105, and a voltage is applied from the alternating-current power supply 106 to the first electrode 102 and the second electrode 105 to permit the EL element 100 to emit light.

In the structure of the dispersion EL element, the light emitting layer is a layer which determines the luminance and efficiency of the dispersion EL element, and particles with a size of 15 μm to 35 μm in particle diameter is used for the inorganic fluorescent substance particles of this light emitting layer. Furthermore, the luminescent color of the light emitting layer of the dispersion EL element is determined by the inorganic fluorescent substance particles used in the light emitting layer. For example, orange light emission is exhibited in the case of using ZnS:Mn for the inorganic fluorescent substance particles, and for example, blue-green light emission is exhibited in the case of using ZnS:Cu for the inorganic fluorescent substance particles. As described above, the luminescent color is determined by the inorganic fluorescent substance particles. Thus, when light of other, for example, white luminescent color is to be emitted, an organic dye is mixed into the organic binder to convert the luminescent color, thereby obtaining the intended luminescent color.

However, light emitters for use in the EL elements have the problems of low light emission luminance and short lifetime.

As a method for increasing the light emission luminance, a method of increasing the voltage applied to the light emitting layer is conceivable. In this case, there is a problem that the half-life of the light output from the light emitter is decreased in proportion to the applied voltage. On the other hand, as a method for making the half-life longer, that is, making the lifetime longer, a method of decreasing the voltage applied to the light emitting layer is conceivable. However, this method has the problem of decrease in light emission luminance. As described above, the light emission luminance and the half-life have a relationship in which when the voltage applied to the light emitting layer is increased or decreased to try to improve one of the light emission luminance and the half-life, the other will be degraded. Therefore, one will have to select either the light emission or the half-life. It is to be noted that the half-time in the specification refers to a period of time until the light output from the light emitter is decreased to the half output of the original luminance.

Thus, long-life electroluminescent devices which emit light with high efficiency have been proposed, as described in Japanese Patent Laid-Open Publication No. 2006-120328. The electroluminescent device is characterized in that a light emitting layer, a dielectric layer, and a charge supply layer between a rear electrode and a transparent electrode, the electron supply layer has an acicular substance, and the electron supply layer further has contact with the both sides of the light emitting layer. Furthermore, the electroluminescent device is characterized in that the acicular substance is a carbon nanotube. According to this method, the use of the acicular substance can supply hot electrons to the light emitting thin film with high efficiency, thereby allowing for a longer lifetime and a higher efficiency.

### SUMMARY

However, since the structure described above belongs to electroluminescent dispersion EL, it is necessary to apply a high alternating voltage between the electrodes for permitting light to be emitted. As a result, the application of a high voltage has the problem of making it harder in principle to obtain higher efficiency, and making it more difficult to obtain a longer lifetime.

Furthermore, it is essential to provide the dielectric layer for an alternating-current light emitting device in the structure described above, and it is necessary to apply a high alternating voltage between the electrodes for the generation of hot electrons in order to permit light to be emitted. As a result, there is the problem of making it harder to obtain a longer lifetime, higher efficiency or a higher light emission luminance.

An object of the present invention is to solve the problems described above, and provide a light emitting device which is driven at a lower voltage with a direct current, exhibits a higher light emission luminance, and has a longer lifetime.

The object described above is achieved by a light emitting device below. That is, a light emitting device of the present invention includes: a pair of electrodes at least one of which is transparent or semi-transparent; and

a phosphor layer arranged between the pair of electrodes,

wherein the phosphor layer contains phosphor particles dispersed therein, and

Conductive nano particles are interposed at the interface between the phosphor layer and one of the electrodes.

Conductive nano particles may be held at the electrode interface of one of the electrodes.

Conductive nano particles may be preferably held on the electrode on the positive electrode side, of the electrodes.

The conductive nano particles held on the electrode side on the positive electrode side may have a work function of 4.5 eV or more.

Conductive nano particles may be held on the electrode on the negative electrode side, of the electrodes.

The conductive nano particles held on the electrode side on the negative electrode side may preferably have a work function of less than 3.5 eV.

The object described above is achieved by a light emitting device below. That is, a light-emitting device of the present invention includes: a pair of electrodes at least one of which is transparent or semi-transparent; and

a phosphor layer arranged between the pair of electrodes,

wherein the phosphor layer contains phosphor particles dispersed therein, and

at least one of the pair of electrodes is provided with a brush-like electrode projecting towards the phosphor layer.

The brush-like electrode may be provided on the electrode on the positive electrode side. The brush-like electrode provided on the electrode on the positive electrode side may preferably have a work function of 4.5 eV or more.

The brush-like electrode may preferably have a length in the range of 0.01 μm to 5 μm.

The brush-like electrode may be formed with conductive nano particles on the electrode.

The conductive nano particles may include at least one metal fine particle selected from the group consisting of Ag, Au, Pt, Ni, and Cu. Further, the conductive nano particles may include at least one oxide fine particle selected from the group consisting of an indium tin oxide, ZnO, and InZnO. Further, the conductive nano particles may include at least one carbon substance fine particle selected from the group consisting of fullerene and carbon nanotube.

The conductive nano particles may preferably have an average particle diameter in the range of 1 to 200 nm.

The phosphor layer may contain a plurality of phosphor particles dispersed in a hole transport material as a medium.

The phosphor layer may contain a hole transport material and a plurality of phosphor particles dispersed in an organic binder as a medium. The hole transport material may include an organic hole transport material including an organic matter. Further, the organic hole transport material may contain components represented by the following chemical formula 1 and chemical formula 2.

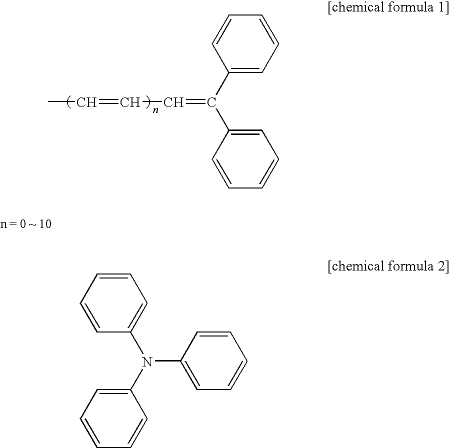

The organic hole transport material may further include at least one component of the group consisting of the following chemical formula 3, chemical formula 4, and chemical formula 5.

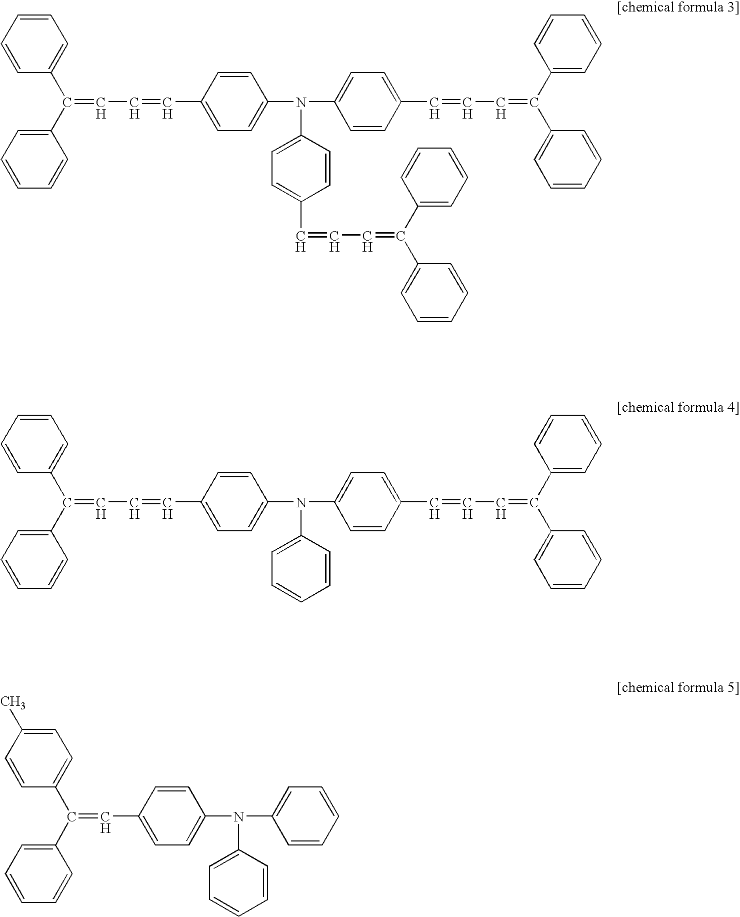

The hole transport material may include an inorganic hole transport material including an inorganic matter.

The phosphor particles may contain a particle including a Group XIII-Group XV compound semiconductor. The phosphor particles may be nitride semiconductor particles comprising at least one element of Ga, Al, and In. The phosphor particles may preferably have an average particle diameter in the range of 0.1 μm to 1000 μm. The phosphor particles may include at least one light emitting material selected from the light emitting materials consisting of a nitride, a sulfide, a selenide, and an oxide.

In the light emitting device according to the present invention, the conductive nano particles held on the electrode serving as the interface with the phosphor layer allow the injection of holes or electrons into the phosphor particles dispersed in the phosphor layer to be improved. This allows light to be emitted at a low voltage with a direct current, and further, allows a light emitter with a higher light emission luminance and a longer lifetime to be provided.

In the light emitting device according to the present invention, the brush-like electrode is formed on the electrode, thereby allowing the injection of holes or electrons into the phosphor particles dispersed in the phosphor layer to be improved. This allows light to be emitted at a low voltage with a direct current, and further, allows a highly efficient light emitting device with a higher light emission luminance and a longer lifetime to be provided.

### BRIEF DESCRIPTION OF THE DRAWINGS

The present invention will become readily understood from the following description of preferred embodiments thereof made with reference to the accompanying drawings, in which like parts are designated by like reference numeral and in which:

FIG. 1 is a schematic cross-sectional view illustrating the structure of a light emitting device according to embodiment 1 of the present invention;

FIG. 2 is a schematic cross-sectional view illustrating the structure of a light emitting device according to modification example 1 from embodiment 1 of the present invention;

FIG. 3 is a schematic cross-sectional view illustrating the structure of a light emitting device according to embodiment 2 of the present invention;

FIG. 4 is a schematic cross-sectional view illustrating the structure of a light emitting device according to modification example 2 from embodiment 2 of the present invention;

FIG. 5 is a schematic cross-sectional view illustrating the schematic structure of a light emitting device according to embodiment 3 of the present invention;

FIG. 6 is a schematic cross-sectional view illustrating the structure of a light emitting device according to modification example 1 from embodiment 3 of the present invention;

FIG. 7 is a schematic cross-sectional view illustrating the structure of a light emitting device according to modification example 2 from embodiment 3 of the present invention;

FIG. 8 is a schematic cross-sectional view illustrating the structure of a light emitting device according to modification example 3 from embodiment 3 of the present invention; and

FIG. 9 is a schematic cross-sectional view illustrating the structure of a conventional light emitting device.

### DESCRIPTION OF PREFERRED EMBODIMENTS

Light emitting elements according to embodiments of the present invention will be described below with reference to the accompanying drawings. It is to be noted that the practically same members are denoted by the same reference numerals in the drawings.

### First Embodiment

### Schematic Structure of EL Element

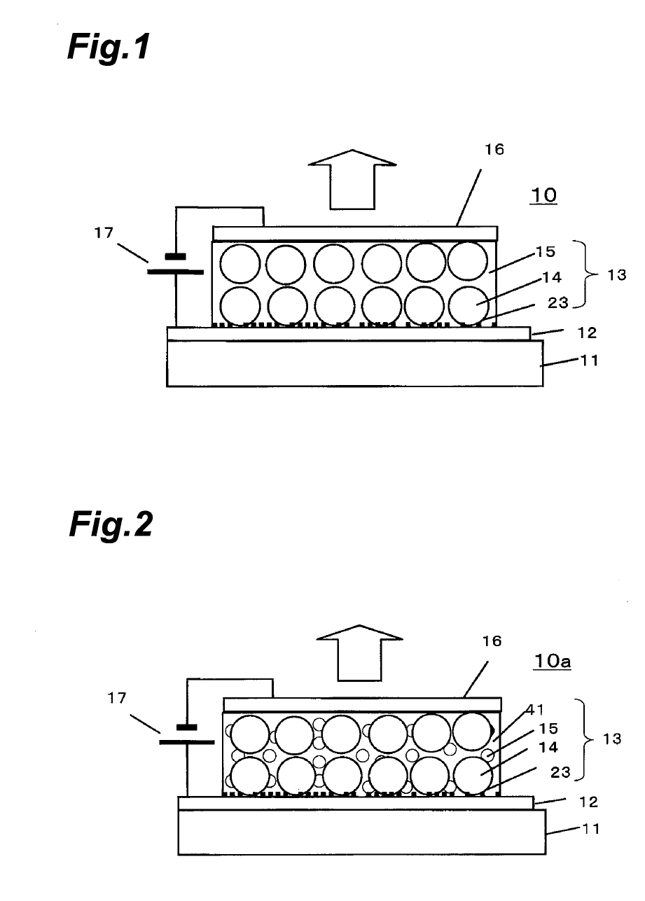

FIG. 1 is a schematic cross-sectional view illustrating the structure of a light emitting element 10 according to first embodiment. This light emitting element 10 includes a rear electrode 12 that is a first electrode, a transparent electrode 16 that is a second electrode, and a phosphor layer 13 sandwiched between the pair of electrodes 12, 16. The phosphor layer 13 contains phosphor particles 14 dispersed in a hole transport material 15. Furthermore, a direct-current power supply 17 is connected between the rear electrode 12 that is the first electrode and the transparent electrode 16 that is the second electrode. In this light emitting device 10, conductive nano particles 23 are held at the interface of the rear electrode 12 on the positive electrode side. When power is supplied between the electrodes 1216, a potential difference is produced between the rear electrode 12 and the transparent electrode 16, thereby applying a voltage therebetween. Then, holes and electrons as carriers are injected from the rear electrode 12 on the positive electrode side and the transparent electrode 16 on the negative electrode side through the conductive nano particles 23 and the hole transport material 15 into the phosphor particles 14, and recombined to emit light. The emitted light is extracted from the transparent electrode 16 side to the outside.

It is to be noted that the present invention is not limited to the structure described above, and changes can be appropriately made, in such a way that the rear electrode 12 and the transparent electrode 16 are interchanged, transparent electrodes are used for both of the electrode 12 and the electrode 16, or an alternating-current power supply is used as the power supply. Furthermore, the phosphor layer 13 may have a structure as shown in FIG. 2 in which phosphor particles 14 and hole transport materials 15 are each dispersed in an organic binder 41.

The respective components of the light emitting element will be described below in detail with reference to FIGS. 1 to 3.

### <Substrate>

In FIG. 1, for the substrate 11, a substrate is used which is able to support respective layers formed on the substrate. Specifically, silicon, ceramics such as Al₂O₃ and AlN, and the like can be used. Furthermore, plastic substrates such as a polyester and a polyimide may be used. In addition, when light is extracted from the side of the substrate 11, the substrate 11 is required to be a light transmitting material with respect to the wavelength of light emitted from a light emitter. As such a material, for example, glass such as Corning 1737, quartz, and the like can be used. In order to prevent alkali ions and the like contained in normal glass from having an effect on the light emitting element, the material may be non-alkali glass, or soda lime glass with a glass surface coated with alumina or the like as an ion barrier layer. These are examples, and the material of the substrate 11 is not considered limited to these examples.

Alternatively, when no light is extracted from the substrate side, the light transmitting property described above is not required, and materials without any light transmitting property can also be used.

### <Electrode>

The electrodes include the rear electrode 12 and the transparent electrode 16. Of the two electrodes, the electrode on the side from which light is extracted is used as the transparent electrode 16, whereas the other is used as the rear electrode 12.

The material of the transparent electrode 16 on the side from which light is extracted may be any material as long as the material has a light transmitting property so that light generated in the phosphor layer 13 can be extracted, and preferably has a high transmittance, in particular, in a visible light region. Furthermore, the material is preferably a low resistance material, and further, preferably has excellent adhesion with the phosphor layer 13. Furthermore, a material is more preferable which can be deposited on the phosphor layer 13 at a low temperature so as to prevent the phosphor layer 13 from being thermally deteriorated. Materials which are particularly preferred as the material of the transparent electrode 16 include, but are not particularly limited to, metal oxides based on an ITO (In₂O₃ doped with SnO₂, which is also referred to as an indium tin oxide), InZnO, ZnO, SnO₂, or the like; metal thin films such as Pt, Au, Pd, Ag, Ni, Cu, Al, Ru, Rh, and Ir; or conductive polymers such as a polyaniline, a polypyrrole, PEDOT/PSS, and a polythiophene. Furthermore, the transparent electrode 16 desirably has a volume resistivity of 1×10⁻³ Ωcm or less, a transmittance of 75% or more for wavelengths from 380 to 780 nm, and a refractive index from 1.85 to 1.95. For example, an ITO can be deposited by a deposition method such as sputtering, electron beam evaporation, or ion plating, for the purpose of improving the transparency or lowering the resistivity. Furthermore, after the deposition, surface treatment such as a plasma treatment may be applied for the purpose of controlling the resistivity. The film thickness of the transparent electrode 16 is determined from the required sheet resistance and visible light transmittance. While the transparent electrode 16 may be directly formed on the phosphor layer 13, the conductive electrode 16 including a transparent conductive film may be formed on a glass substrate and attached so that the transparent conductive film comes in contact with the phosphor layer 13.

The rear electrode 12 on the side from which no light is extracted may be any electrode as long as the electrode is electrically conductive and has excellent adhesion with the substrate 11 and the phosphor layer 13. As preferred examples, for example, metal oxides such as ITO, InZnO, ZnO, and SnO₂, metals such as Pt, Au, Pd, Ag, Ni, Cu, Al, Ru, Rh, Ir, Cr, Mo, W, Ta, Nb, and laminated structures thereof, or conductive polymers such as a polyaniline, a polypyrrole, PEDOT [poly(3,4-ethylene dioxythiophene)]/PSS (polyethylene sulfonic acid), or conductive carbon can be used.

The rear electrode 12 may be configured to cover the entire surface of the layer, or may be configured to have a plurality of stripe-shaped electrodes in the layer. Furthermore, the rear electrode 12 and the transparent electrode 16 may be configured to have a plurality of stripe-shaped electrodes, in such a way that each stripe-shaped electrode of the rear electrode 12 and all of the strip-shaped electrodes of the transparent electrode 16 have a skew relationship with each other and that projections of each stripe-shaped electrode of the rear electrode 12 onto the light emitting surface and projections of all of the stripe-shaped electrodes of the rear electrode 16 onto the light emitting surface intersect with each other. In this case, the application of a voltage to the electrodes selected respectively from the respective stripe-shaped electrodes of the rear electrode 12 and the respective striped-shaped electrodes of the transparent electrode 16 allows a display to be configured in such a way that light is emitted in a predetermined position. It is to be noted that the same applies to the structure in FIG. 2.

### <Conductive Nano Particles>

In the light emitting device according to embodiment 1 of the present invention, the conductive nano particles 23 are held at the interface of the electrode 12 on the positive electrode side. Furthermore, as shown in a light emitting device according to embodiment 2, conductive nano particles 24 may be held at the electrode interface on the negative electrode side. The conductive nano particles 23, 24 used for the light emitting elements according to the present invention can use metal material particles such as Ag, Au, Pt, Ni, and Cu, oxide particles such as an indium tin oxide, ZnO, and InZnO, carbon material particles such as carbon nanotubes. The shapes of the conductive nano particles 23 may be any shape such as granular, circular, columnar, acicular, or amorphous. The average particle diameter or average length of the conductive nano particles 23 preferably falls within the range of 1 nm to 200 nm. The average particle diameter or average length less than 1 nm results in poor conductivity, decreasing the light emission luminance. On the other hand, the average particle diameter or average length greater than 200 nm increases electrical conduction between the electrodes, while the number of the phosphor particles 14 which are not included in the conductive path is increased, decreasing the light emission luminance and efficiency. The production of carbon nanotubes is carried out by a method such as a vapor phase synthetic method or plasma method, and depending on the manufacturing conditions, the electrical characteristics, diameters, lengths, and the like of the carbon nanotubes can be arbitrarily varied. In the case of holding a carbon nanotube at the electrode interface on the positive electrode side, it is preferable to use a p-type carbon nanotube as the carbon nanotube. In the case of holding a carbon nanotube at the electrode interface on the negative electrode side, it is preferable to use an n-type carbon nanotube as the carbon nanotube. The p-type carbon nanotube is obtained by doping a carbon nanotube with a Group V element such as phosphorus, whereas the n-type carbon nanotube is obtained by doping a carbon nanotube with a Group III element such as nitrogen.

### <Phosphor Layer>

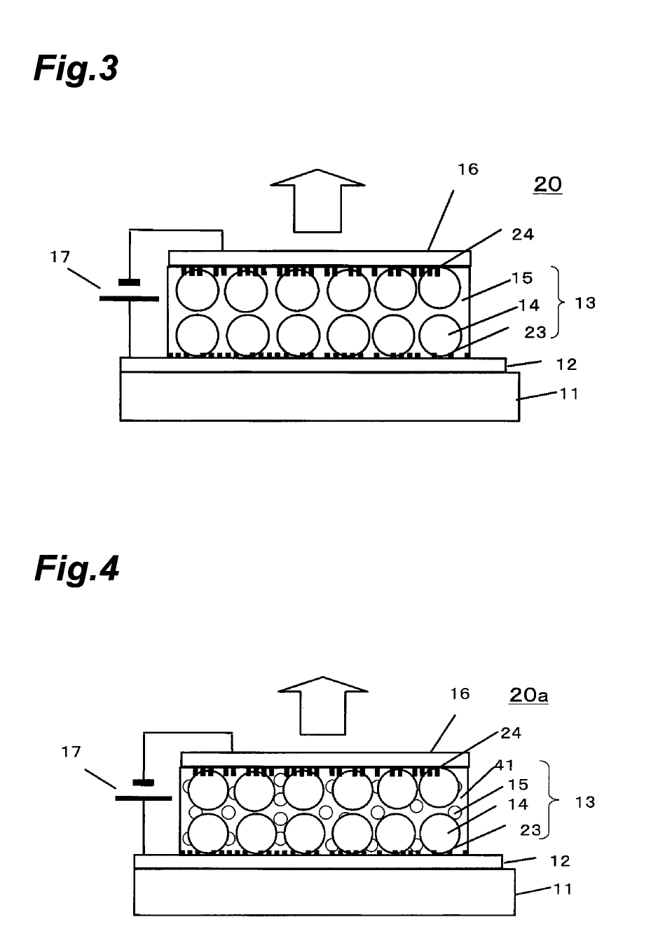

The phosphor layer 13 contains the phosphor particles 14 dispersed in the hole transport material 15 as a medium (FIG. 1, FIG. 3). It is to be noted that the phosphor layer 13 is not limited to this example, and may contain the phosphor particles 14 and the hole transport material 15 each dispersed in the organic binder 41 (FIG. 2, FIG. 4).

### <Phosphor Particles>

As the phosphor particles 14, any material can be used as long as the optical bandgap of the material is as wide as visible light. Specifically, AlN, GaN, InN, AlP, GaP, InP, AlAs, GaAs, AlSb, and the like which are Group XIII-Group XV compound semiconductors can be used. In particular, Group XIII nitride semiconductors typified by GaN are preferable. Furthermore, mixed crystals thereof (for example, GaInN, etc.) may be used. Moreover, in order to control the conductivity, the material may contain, as a dopant, one or more elements selected from the group consisting of Si, Ge, Sn, C, Be, Zn, Mg, Ge, and Mn.

Furthermore, with a nitride such as InGaN or AlGaN, ZnSe or ZnS, or further ZnS, ZnSe, GaP, CdSe, CdTe, SrS, CaS, or ZnO as a mother body, the mother body can be used as it is, or phosphor particles can be used with the addition of one or more elements selected from Ag, Al, Ga, Cu, Mn, Cl, Tb, and Li as an additive. In addition, multicomponent compounds such as ZnSSe and thiogallate based phosphor can be also used.

Furthermore, the multiple compositions in the phosphor particles 14 may have a laminated structure or a segregated structure. The phosphor particles 14 may have a particle diameter in the range of 0.1 μm to 1000 μm, more preferably, in the range of 0.5 μm to 500 μm.

### <Hole Transport Material>

Next, the hole transport material 15 will be described, which serves as a medium in which the phosphor particles 14 are dispersed or is dispersed in the organic binder 41 along with the phosphor particles 14. As the hole transport material 15, there are organic hole transport materials and inorganic hole transport materials. Materials which have a high hole mobility are preferable for the hole transport material 15.

### <Organic Hole Transport Material>

This organic hole transport material preferably contains components of the following chemical formula 6 and chemical formula 7.

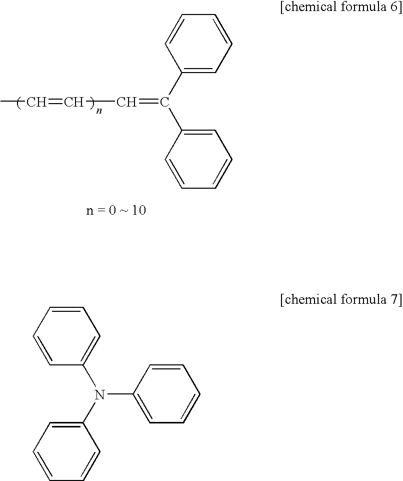

It is believed that the advantageous effect of the organic hole transport material containing the components of the above chemical formula 6 and chemical formula 7 is efficient injection of holes for the phosphor particles 14.

Furthermore, this organic hole transport material may contain any of the following chemical formula 8, chemical formula 9, and chemical formula 10 as a component.

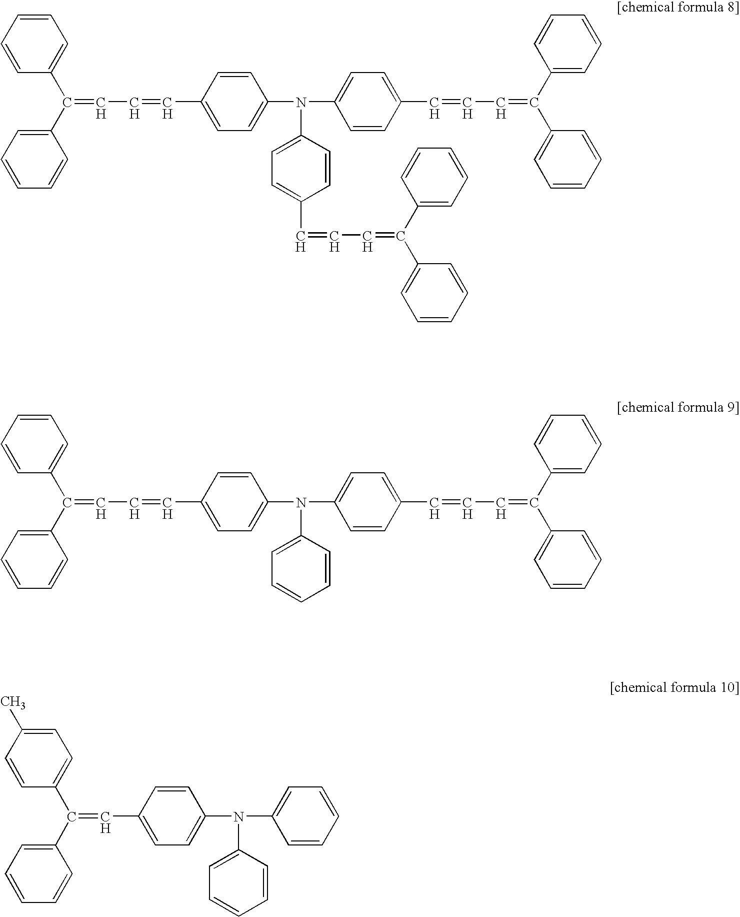

In addition, the main types of organic hole transport materials are low-molecular-weight materials and high-molecular-weight materials. Low-molecular-weight materials which have a hole transport property include diamine derivatives used by Tang et al., such as N,N′-bis(3-methylphenyl)-N,N′-diphenylbenzidine (TPD) and N,N′-bis(α-naphthyl)-N,N′-diphenylbenzidine (NPD), in particular, diamine derivatives which has a Q1-G-Q2 structure, disclosed in Japanese Patent No. 2037475, where Q1 and Q2 are separately a group having a nitrogen atom and at least three carbon chains (at least one of the carbon chains comes from an aromatic group), and G is a linking group including a cycloalkylene group, an arylene group, an alkylene group or a carbon-carbon bond. Alternatively, the organic hole transport material may be polymers (oligomers) including these structural units. These polymers include polymers which have a Spiro structure or a dendrimer structure. Furthermore, the form in which molecules of a low-molecular-weight hole transport material are dispersed in a nonconductive polymer is likewise available. Specific examples of the molecular dispersion system include an example in which molecules of TPD are dispersed in high concentration in a polycarbonate, with the hole mobility on the order of 10⁻⁴ to 10⁻⁵ cm²/Vs.

On the other hand, high-molecular-weight materials which has a hole transport property include π-conjugated polymers and σ-conjugated polymers, and for example, a high-molecular-weight material in which an arylamine compound is incorporated. Specifically, the high-molecular-weight materials include, but are not limited to, poly-para-phenylenevinylene derivatives (PPV derivatives), polythiophenes derivatives (PAT derivatives), polyparaphenylene derivatives (PPP derivatives), polyalkylphenylene (PDAF), polyacetylene derivatives (PA derivatives), and polysilane derivatives (PS derivatives). Furthermore, the high-molecular-weight materials may be polymers with a low-molecular-weight hole-transport molecular structure incorporated into their molecular chains, and specific examples of the polymers include polymethacrylamides with an aromatic amine in their side chains (PTPAMMA, PTPDMA) and polyethers with an aromatic amine in their main chains (TPDPES, TPDPEK). Above all, as a particularly preferred example, above all, poly-N-vinylcarbazole (PVK) exhibits an extremely high hole mobility of 10⁻⁶ cm²/Vs. Other specific examples include PEDOT/PSS and polymethylphenylsilane (PMPS).

Moreover, more than one type of the hole transport materials mentioned above may be mixed and used. Furthermore, the organic hole transport material may contain a crosslinkable or polymerizable material which is cross-linked or polymerized by light or heat.

### <Inorganic Hole Transport Material>

Inorganic hole transport materials will be described. The inorganic hole transport material may be any material as long as the material is transparent or semi-transparent and exhibits p-type conductivity. Preferred inorganic hole transport materials include metalloid semiconductors such as Si, Ge, SiC, Se, SeTe, and As₂Se₃; binary compound semiconductor such as ZnS, ZnSe, CdS, ZnO, and CuI; chalcopyrite semiconductors such as CuGaS₂, CuGaSe₂, and CuInSe₂, and further mixed crystals of these semiconductors; and oxide semiconductors such as CuAlO₂ and CuGaO₂, and further mixed crystals of these semiconductors. Moreover, a dopant may be added to these materials, in order to control the conductivity.

### Modification Example 1

FIG. 2 is a schematic cross-sectional view illustrating the structure of a light emitting device 10a according to modification example 1 of embodiment 1. This light emitting device 10a is different as compared with the light emitting device 10 according to embodiment 1, in that the phosphor layer 13 contains the phosphor particles 14 and the hole transport material 15 dispersed in the organic binder 41 as a medium.

### <Organic Binder>

As the organic binder 41 in the phosphor layer 13 of the light emitting device 10a according to the modification example, in which the phosphor particles 14 and the hole transport material 15 are each dispersed, any material can be used such as a resin solution as long as the material can be mixed with the hole transport material 15.

### Example 1

As example 1 of the present invention, a method for obtaining the light emitting device in FIG. 1 by an application method will be described. As the example, a light emitting device was manufactured as shown in FIG. 1.

(a) First, a Pt film 12 of about 300 nm as a rear electrode was formed on a silicon substrate 11 by sputtering.

(b) Next, Fe nano particles with an average particle diameter of 1 to 3 nm were formed on the Pt film 12 similarly by sputtering. Then, the substrate was heated to about 800° C., and a hydrocarbon gas was introduced into the chamber to grow carbon nanotubes 23 as conductive nano particles. The obtained carbon nanotubes had a diameter of 1 to 10 nm and a length of 50 nm to 120 nm.

(c) Next, 75 weight % tetraphenylbutadiene T770 as the hole transport material 15 was mixed into a resin solution from Du Pont, and furthermore, as the phosphor particles, GaN particles 14 with an average particle diameter of 500 to 1000 nm were well mixed to obtain a light emitting paste.

(d) Then, the manufactured light emitting paste was applied on the Pt film 12 with the carbon nanotubes 23 held thereon, and then dried. The thickness of the applied film was about 30 μm.

(e) As an opposed substrate with a transparent electrode, a glass substrate was used with an ITO film 16 as a transparent conductive film deposited thereon by sputtering. The film thickness of the ITO film 16 was about 300 nm.

(f) Subsequently, the substrates were attached so that the surface of the ITO film 16 comes in contact with the light emitting paste.

The light emitting device 10 was obtained in the way described above. The evaluation of the light emitting device was carried out by applying a direct-current voltage between the rear electrode 12 and the transparent electrode 16. Furthermore, the luminance measurement was carried out with the use of a portable luminance meter. The results show that the light emitting device started to emit orange light at a direct-current voltage of about 5 V and produced a light emission luminance of about 3500 cd/m² at 15 V.

As described above, according to the present invention, a light emitting device can be obtained which is driven at a low voltage with a direct current and exhibits a high light emission luminance.

### ADVANTAGEOUS EFFECTS

The light emitting devices 10, 10a according to embodiment 1 has a better electro injection property, and can provide a higher luminance and a longer lifetime than conventional light emitting devices.

### Second Embodiment

FIG. 3 is a schematic cross-sectional view illustrating the structure of a light emitting device 20 according to second embodiment of the present invention. This light emitting device 20 is different as compared with the light emitting devices according to first embodiment, in that separate conductive nano particles 24 are held at the electrode interface on the negative electrode side. Trough the conductive nano particles 24 held on the transparent electrode 16 on the negative electrode side, electrons can be injected into the phosphor particles 14.

### Modification Example 2

FIG. 4 is a schematic cross-sectional view illustrating the structure of a light emitting device 20a according to a modification example 2 from embodiment 2 of the present invention. This light emitting device 20a is different as compared with the light emitting device 20 according to embodiment 2, in that a phosphor layer 13 contains phosphor particles 14 and a hole transport material 15 dispersed in an organic binder 41 as a medium.

### Example 2

As example 2 of the present invention, a method for manufacturing the light emitting device 20 shown in FIG. 3 by an application method will be described.

(a) First, a Pt film 12 of about 300 nm as a rear electrode was formed on a silicon substrate 11 by sputtering.

(b) Next, Fe nano particles with an average particle diameter of 1 to 3 nm were formed on the Pt film 12 similarly by sputtering. Then, the substrate was heated to about 800° C., and a hydrocarbon gas was introduced into the chamber to grow carbon nanotubes 23 as conductive nano particles. The obtained carbon nanotubes had a diameter of 1 to 10 nm and a length of 50 nm to 120 nm.

(c) Next, 75 weight % tetraphenylbutadiene T770 as the hole transport material 15 was mixed into a resin solution from Du Pont, and furthermore, as the phosphor particles, GaN particles 14 with an average particle diameter of 500 to 1000 nm were well mixed to obtain a light emitting paste.

(d) Then, the manufactured light emitting paste was applied on the Pt film 12 with the carbon nanotubes 23 held thereon, and then dried. The thickness of the applied film was about 30 μm.

(e) As an opposed substrate with a transparent electrode, a glass substrate was used with an ITO film 16 as a transparent conductive film deposited thereon by sputtering. The film thickness was about 300 nm.

(f) Next, a resin solution with ITO nano particles 24 mixed therein as conductive nano particles was applied on the surface of the ITO film 16 by spin coating.

(g) Subsequently, the substrates were attached so that the surface of the ITO film 16 with the nano particles 24 held thereon comes in contact with the previously applied light emitting paste.

The light emitting device 20 was obtained in the way described above. The evaluation of the light emitting device was carried out by applying a direct-current voltage between the rear electrode 12 and the transparent electrode 16. Furthermore, the luminance measurement was carried out with the use of a portable luminance meter. The results show that the light emitting device started to emit orange light at a direct-current voltage of about 4 V and produced a light emission luminance of about 5000 cd/m² at 12 V.

As described above, according to the present invention, a light emitting device can be obtained which is driven at a low voltage with a direct current and exhibits a high light emission luminance.

### Third Embodiment

### Schematic Structure of EL Element

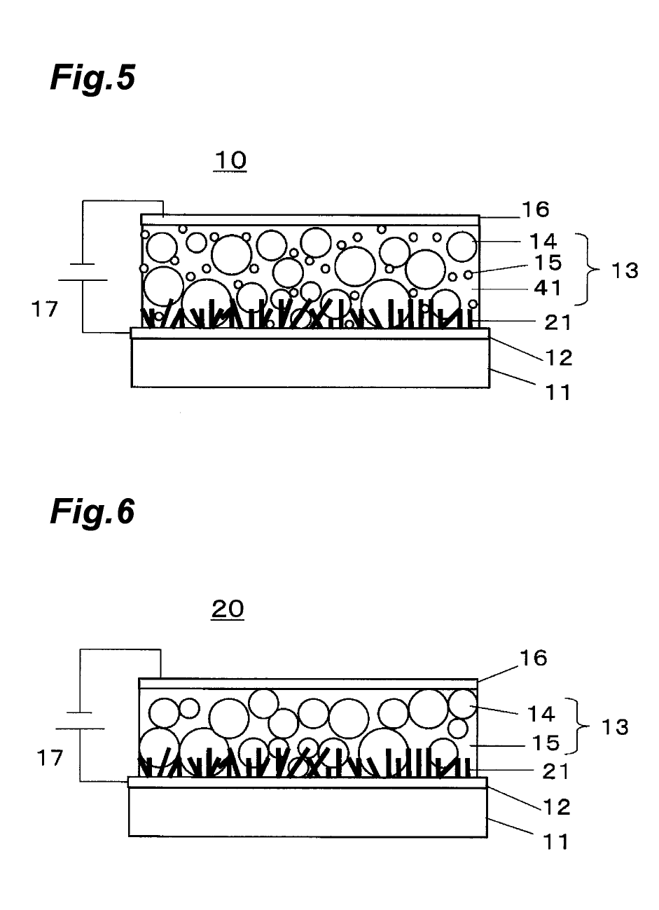

FIG. 5 is a side view illustrating the structure of a light emitting device 10 according to third embodiment. This light emitting device 10 has a phosphor layer 13 sandwiched between an electrode 12 as a first electrode, formed on a substrate 11, and a transparent conductive film 16 as a second electrode. The phosphor layer 13 contains phosphor particles 14 and a hole transport material 15 mixed and dispersed in an organic binder 41 as a medium. Furthermore, this light emitting device 10 is characterized in that a brush-like electrode 21 for hole injection, which projects into the phosphor layer 13, is formed on the surface of the electrode 12 on the positive electrode side. When power is supplied between the electrodes 12, 16, a potential difference is produced between the rear electrode 12 and the transparent electrode 16, thereby applying a voltage therebetween. Then, holes and electrons are injected respectively from the rear electrode 12 and the transparent electrode 16 into the phosphor particles 14, and recombined to emit light. In embodiment 3, a direct-current power supply 17 is used as a power supply.

It is to be noted that the embodiment is not limited to the structure described above, changes can be appropriately made, in such a way that the rear electrode 12 and the transparent electrode 16 are interchanged, transparent electrodes are used for both of the electrode 12 and the electrode 16, or an alternating-current power supply is used as the power supply.

Furthermore, while the brush-like electrode 21 is formed only on the electrode 12 on the positive electrode side in this light emitting device 10, the light emitting device 10 is not limited to this structure, and as shown in FIG. 8, a brush-like electrode 22 for electron injection may be further formed on the surface of the electrode 16 on the negative electrode side.

The respective components of the light emitting device 10 will be described below.

### <Substrate>

In FIG. 5, for the substrate 11, a substrate is used which is able to support respective layers formed on the substrate. Specifically, silicon, ceramics such as Al₂O₃ and AlN, and furthermore, plastic substrates such as a polyester and a polyimide can be used. In addition, when light is extracted from the side of the substrate 11, the substrate 11 is required to be a light transmitting material with respect to the wavelength of light emitted from a light emitter. As such a material, for example, glass such as Corning 1737, quartz, and the like can be used. In order to prevent alkali ions and the like contained in normal glass from having an effect on the light emitting device, the material may be non-alkali glass, or soda lime glass with a glass surface coated with alumina or the like as an ion barrier layer. It is to be noted that these are examples, and the material of the substrate 11 is not considered limited to these examples.

Alternatively, when no light is extracted from the substrate side, the light transmitting property described above is not required, and materials without any light transmitting property can also be used.

It is to be noted that in the case of forming the brush-like electrode 22 for electron injection on the transparent electrode 16 as shown in FIG. 8, a transparent heat and resistance substrate such as sapphire may be used, with a Pt, Au film of 30 nm or less in film thickness, or a tin oxide film formed thereon.

### <Electrodes>

It is to be noted that while there are the rear electrode 12 and the transparent electrode 16 as electrodes, description thereof will be omitted because the rear electrode 12 and the transparent electrode 16 are substantially the same as the rear electrode 12 and transparent electrode 16 according to embodiment 1 described above.

### <Brush-like Electrode>

In the light emitting device 10 according to embodiment 3 of the present invention, the brush-like electrode 21 projecting into the phosphor layer 13 is formed on the electrode 12 on the positive electrode side as shown in the side view of FIG. 5. It is to be noted that FIG. 5 is a side view, in which the brush-like electrode 21 and phosphor particles 14 are merely overlapped with each other. The brush-like electrode 21 on the positive electrode side preferably has a work function of 4.0 eV or more. Each brush of the brush-like electrode 21 preferably has a diameter in the range of 1 nm to 200 nm, and further, more preferably in the range of 1 nm to 100 nm. Furthermore, each brush preferably has a length in the range of 0.01 μm to 5 μm, and further, more preferably in the range of 0.01 μm to 3 μm. The brush-like electrode 21 is provided with flexibility by selecting the size of the brush-like electrode 21, and the length mentioned above allows the surfaces of the phosphor particles 14 and the brush-like electrode to be sufficiently brought into contact with each other even when the phosphor particles 14 has a distribution in size or shape, resulting in effective injection of holes and electrons. This brush-like electrode 21 may be formed with conductive nano particles held thereon. It is to be noted that while the light emitting device 10 has the brush-like electrode 21 formed only on the electrode 12 on the positive electrode side, the light emitting device 10 is not limited to this structure, and a brush-like electrode 22 for injection of electrons may also be formed on the electrode 16 on the negative electrode side, as shown in modification example 3.

### <Conductive Nano Particles>

The conductive nano particles used for the brush-like electrode 21 can use metal material particles such as Ag, Au, Pt, Ni, and Cu, oxide particles such as an indium tin oxide, ZnO, and InZnO, carbon material particles such as carbon nanotubes. The shapes of the conductive nano particles may be any shape such as granular, circular, columnar, acicular, or amorphous. The average particle diameter of the conductive nano particles 23 preferably falls within the range of 1 nm to 200 nm, and further, more preferably within the range of 1 nm to 100 nm. The average particle diameter or average length less than 1 nm results in poor conductivity, decreasing the light emission luminance. On the other hand, the average particle diameter or average length greater than 200 nm increases electrical conduction between the electrodes, while the number of the phosphor particles 14 which are not included in the conductive path is increased, decreasing the light emission luminance and efficiency.

The production of carbon nanotubes is carried out by a method such as a vapor phase synthetic method or plasma method, and depending on the manufacturing conditions, the electrical characteristics, diameters, lengths, and the like of the carbon nanotubes can be arbitrarily varied. In the case of holding a carbon nanotube at the electrode interface on the positive electrode side, it is preferable to use a p-type carbon nanotube as the carbon nanotube. In the case of holding a carbon nanotube at the electrode interface on the negative electrode side, it is preferable to use an n-type carbon nanotube as the carbon nanotube. The p-type carbon nanotube is obtained by doping a carbon nanotube with a Group V element such as phosphorus, whereas the n-type carbon nanotube is obtained by doping a carbon nanotube with a Group III element such as nitrogen.

### <Phosphor Layer>

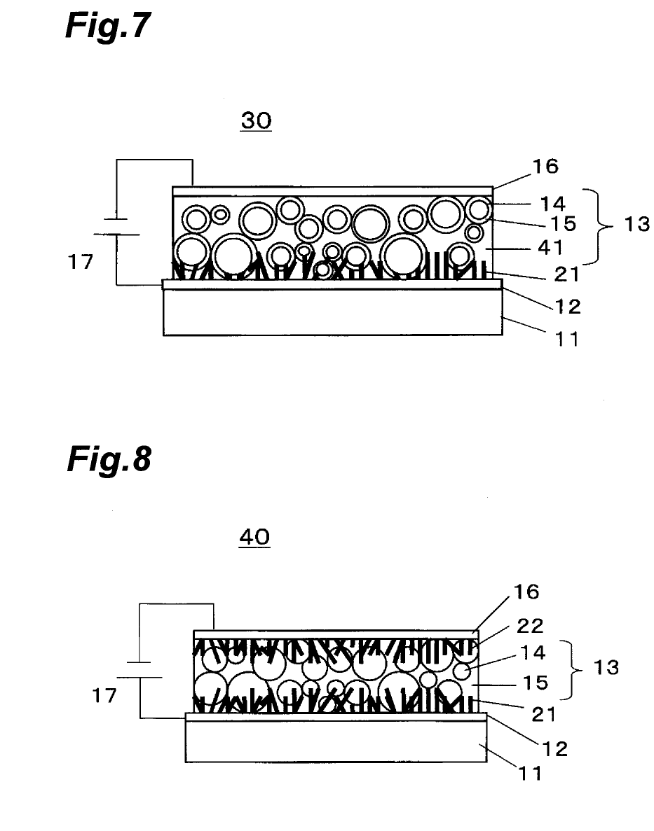

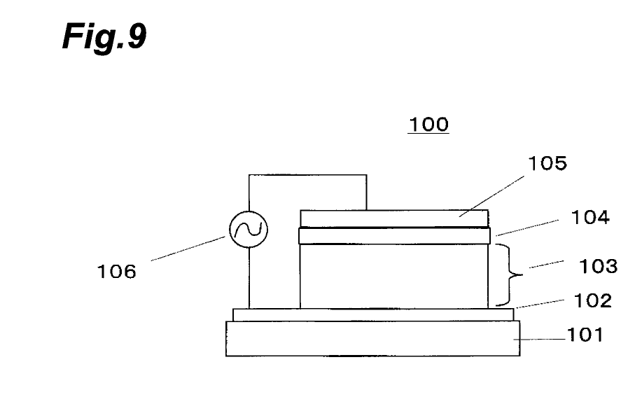

The phosphor layer 13 contains the phosphor particles 14 and the hole transport material 15 each dispersed in the organic binder 41 (FIG. 5). It is to be noted that the phosphor layer 13 is not limited to this example, and may contain phosphor particles 14 dispersed in a hole transport material 15 as a medium, as in modification example 1 (FIG. 6). Alternatively, as in modification example 2, the phosphor layer 13 may be configured in such a way that phosphor particles with their surfaces covered with a hole transport material 15 are dispersed in an organic binder 41 as a medium (FIG. 7).

### <Organic Binder>

As the organic binder 41 with the phosphor particles 14 and the hole transport material 15 are each dispersed therein, any material can be used as long as the material can be mixed with the hole transport material 15, and a resin solution and the like can be used.

### <Phosphor Particles>

As the phosphor particles 14, any material can be used as long as the optical bandgap of the material is as wide as visible light. Specifically, AlN, GaN, InN, AlP, GaP, InP, AlAs, GaAs, AlSb, and the like which are Group XIII-Group XV compound semiconductors can be used. In particular, Group XIII nitride semiconductors typified by GaN are preferable. Furthermore, mixed crystals thereof (for example, GaInN, etc.) may be used. Moreover, in order to control the conductivity, the material may contain, as a dopant, one or more elements selected from the group consisting of Si, Ge, Sn, C, Be, Zn, Mg, Ge, and Mn.

Furthermore, with a nitride such as InGaN or AlGaN, ZnSe or ZnS, or further ZnS, ZnSe, GaP, CdSe, CdTe, SrS, CaS, or ZnO as a mother body, the mother body can be used as it is, or phosphor particles can be used with the addition of one or more elements selected from Ag, Al, Ga, Cu, Mn, Cl, Tb, and Li as an additive. In addition, multicomponent compounds such as ZnSSe and thiogallate based phosphor can be also used.

Furthermore, the multiple compositions in the phosphor particles 14 may have a laminated structure or a segregated structure. The phosphor particles 14 may have a particle diameter in the range of 0.1 μm to 1000 μm, more preferably, in the range of 0.5 μm to 500 μm.

### <Hole Transport Material>

Next, the hole transport material 15 will be described, which serves as a medium in which the phosphor particles 14 are dispersed or is dispersed in the organic binder 41 along with the phosphor particles 14. It is to be noted that the surfaces of the phosphor particles 14 may be covered with the hole transport material 15, as in the case of modification example 2. As the hole transport material 15, there are organic hole transport materials and inorganic hole transport materials. A materials which has a high hole mobility is preferable for the hole transport material 15.

### <Organic Hole Transport Material>

This organic hole transport material preferably contains components of the following chemical formula 6 and chemical formula 7 described in embodiment 1.

It is believed that the advantageous effect of the organic hole transport material containing the components of the above chemical formula 6 and chemical formula 7 is efficient injection of holes for the phosphor particles 14.

Furthermore, this organic hole transport material may contain, as a component, any of the following chemical formula 8, chemical formula 9, and chemical formula 10 described in embodiment 1.

In addition, the main types of organic hole transport materials are low-molecular-weight materials and high-molecular-weight materials. Description of these organic hole transport materials will be omitted because substantially the same materials as described in embodiment 1 can be used likewise for the organic hole transport materials.

### <Inorganic Hole Transport Material>

The inorganic hole transport materials will be described. Description of these inorganic hole transport materials will be omitted because substantially the same materials as described in embodiment 1 can be used likewise for the inorganic hole transport materials.

### Example 1

As example 1 of the present invention, a method for obtaining the light emitting device 10 in FIG. 5 by an application method will be described. As the example, the light emitting device 10 was manufactured as shown in FIG. 5.

(a) First, a Pt film of about 300 nm as the rear electrode 12 was formed on a silicon substrate 11 by sputtering.

(b) Next, Fe nano particles with an average particle diameter of 1 to 3 nm were formed on the Pt film 12 similarly by sputtering. Then, the substrate was heated to about 800° C., and a hydrocarbon gas was introduced into the chamber to grow carbon nanotubes 21 in the Fe nano particles. The obtained carbon nanotubes had a diameter of 1 to 10 nm and a length of 0.5 μm to 2 μm, which had a brush shape grown in a direction substantially perpendicular to the surface of the Pt film 12 as an electrode.

(c) Next, 50 weight % tetraphenylbutadiene T770 (trade name) as the hole transport material 15 was dissolved and mixed into a resin solution from Du Pont as the organic binder 41, and furthermore, as the phosphor particles, GaN particles 14 with an average particle diameter of 500 to 1000 nm were well mixed to obtain a light emitting paste.

(d) Then, the manufactured light emitting paste was applied on the substrate with the brush-like carbon nanotubes 21 held thereon, and then dried. The thickness of the applied film was about 30 μm.

(e) As an opposed substrate with the transparent electrode 16, a glass substrate was used with an ITO as the transparent conductive film 16 deposited thereon by sputtering. The film thickness was about 300 nm.

(f) Subsequently, after drying the light emitting paste, the substrates were attached so that the surface of the ITO comes in contact with the light emitting paste.

The light emitting device 10 was obtained in the way described above. The evaluation of the light emitting device was carried out by applying a direct-current voltage between the rear electrode 12 and the transparent electrode 16. Furthermore, the luminance measurement was carried out with the use of a portable luminance meter. The results show that the light emitting device started to emit orange light at a direct-current voltage of about 4 V and produced a light emission luminance of about 5000 cd/m² at 12 V.

As described above, according to the present invention, a light emitting device can be obtained which is driven at a low voltage with a direct current and exhibits a high light emission luminance.

### ADVANTAGEOUS EFFECTS

The light emitting device according to example 1 has better corrosion resistance and oxidation resistance, and can provide a higher luminance and a longer lifetime than conventional light emitting devices.

### Modification Example 1

FIG. 6 is a schematic cross-sectional view illustrating the structure of a light emitting device 20 according to modification example 1 from embodiment 3. This light emitting device 20 is different as compared with the light emitting device 10 according to embodiment 3, in that a phosphor layer 13 contains phosphor particles 14 dispersed in a hole transport material 15 as a medium.

### Modification Example 2

FIG. 7 is a side view illustrating the structure of a light emitting device 30 according to modification example 2 from embodiment 3. This light emitting device 30 is different as compared with the light emitting device 10 according to embodiment 3, in that a phosphor layer 13 is configured in such a way that phosphor particles 14 with their surfaces covered with a hole transport material 15 are dispersed in an organic binder 41 as a medium.

### Modification Example 3

FIG. 8 is a side view illustrating the structure of a light emitting device 40 according to modification example 3 from embodiment 3. This light emitting device 40 has a phosphor layer 13 containing phosphor particles 14 dispersed in a hole transport material 15 as a medium, as in the case of the light emitting device 20 according to modification example 1 from embodiment 3. Furthermore, this light emitting device 40 is characterized in that a brush-like electrode 22 is also formed on the electrode 16 on the negative electrode side. The brush-like electrode 22 formed on the electrode 16 on the negative electrode side allows electron injection into the phosphor layer 13 to be efficiently carried out.

The light emitting elements according to the present invention have a high light emission luminance, and thus are available for backlights for LCDs illumination, displays, etc.

1. A light emitting device comprising:
a pair of electrodes at least one of which is transparent or semi-transparent; and
a phosphor layer arranged between the pair of electrodes,
wherein the phosphor layer contains phosphor particles dispersed therein, and
conductive nano particles are interposed at the interface between the phosphor layer and one of the electrodes.

2. The light emitting device according to claim 1, wherein conductive nano particles are held at the electrode interface of one of the electrodes.

3. The light emitting device according to claim 2, wherein conductive nano particles are held on the electrode on the positive electrode side, of the electrodes.

4. The light emitting device according to claim 3, wherein the conductive nano particles held on the electrode side on the positive electrode side have a work function of 4.5 eV or more.

5. The light emitting device according to claim 2, wherein conductive nano particles are held on the electrode on the negative electrode side, of the electrodes.

6. The light emitting device according to claim 5, wherein the conductive nano particles held on the electrode side on the negative electrode side have a work function of less than 3.5 eV.

7. A light emitting device comprising:
a pair of electrodes at least one of which is transparent or semi-transparent; and
a phosphor layer arranged between the pair of electrodes,
wherein the phosphor layer contains phosphor particles dispersed therein, and
at least one of the pair of electrodes is provided with a brush-like electrode projecting towards the phosphor layer.

8. The light emitting device according to claim 1, wherein the brush-like electrode is provided on the electrode on the positive electrode side.

9. The light emitting device according to claim 2, wherein the brush-like electrode provided on the electrode on the positive electrode side has a work function of 4.5 eV or more.

10. The light emitting device according to claim 1, wherein the brush-like electrode has a length in the range of 0.01 μm to 5 μm.

11. The light emitting device according to claim 1, wherein the brush-like electrode is formed with conductive nano particles on the electrode.

12. The light emitting device according to claim 1, wherein the conductive nano particles comprises at least one metal fine particle selected from the group consisting of Ag, Au, Pt, Ni, and Cu.

13. The light emitting device according to claim 1, wherein the conductive nano particles comprises at least one oxide fine particle selected from the group consisting of an indium tin oxide, ZnO, and InZnO.

14. The light emitting device according to claim 1, wherein the conductive nano particles comprises at least one carbon substance fine particle selected from the group consisting of fullerene and carbon nanotube.

15. The light emitting device according to claim 1, wherein the conductive nano particles have an average particle diameter in the range of 1 nm to 200 nm.

16. The light emitting device according to claim 1, wherein the phosphor layer contains a plurality of phosphor particles dispersed in a hole transport material as a medium.

17. The light emitting device according to claim 1, wherein the phosphor layer contains a hole transport material and a plurality of phosphor particles dispersed in an organic binder as a medium.

18. The light emitting device according to claim 1, wherein the phosphor layer is configured in such a way that phosphor particles with their surfaces covered with a hole transport material are dispersed in an organic binder as a medium.

19. The light emitting device according to claim 16, wherein the hole transport material comprises an organic hole transport material including an organic matter.

20. The light emitting device according to claim 19, wherein the organic hole transport material contains components represented by the following chemical formula 1 and chemical formula 2.

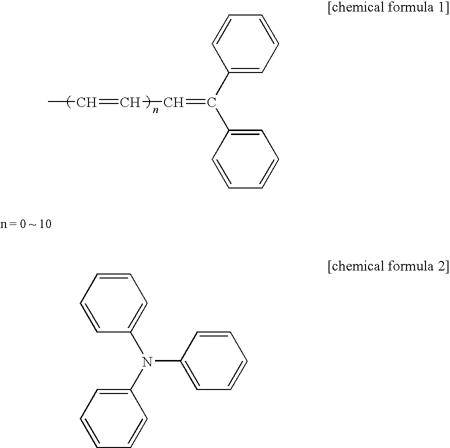

21. The light emitting device according to claim 20, wherein the organic hole transport material further comprises at least one component of the group consisting of the following chemical formula 3, chemical formula 4, and chemical formula 5.

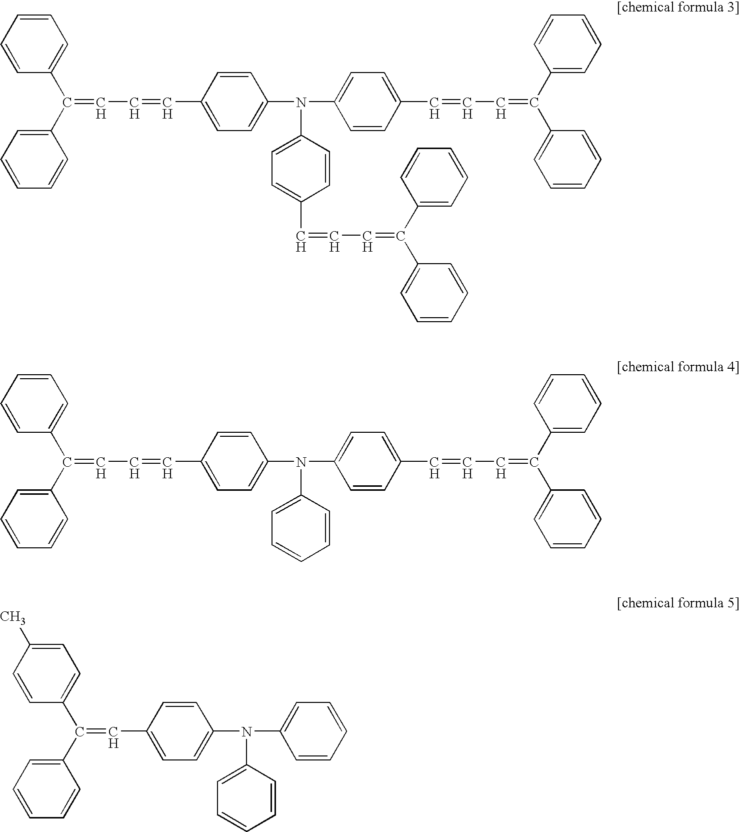

22. The light emitting device according to claim 16, wherein the hole transport material comprises an inorganic hole transport material including an inorganic matter.

23. The light emitting device according to claim 1, wherein the phosphor particles contains a particle including a Group XIII-Group XV compound semiconductor.

24. The light emitting device according to claim 23, wherein the phosphor particles are nitride semiconductor particles comprising at least one element of Ga, Al, and In.

25. The light emitting device according to claim 23, wherein the phosphor particles have an average particle diameter in the range of 0.1 μm to 1000 μm.

26. The light emitting device according to claim 1, wherein the phosphor particles comprise at least one light emitting material selected from the light emitting materials consisting of a nitride, a sulfide, a selenide, and an oxide.
